(19) United States
(12) Patent Application Publication
(10) Pub. No.: US 2014/0239434 A1
(43) Pub. Date: Aug. 28, 2014

(54) SEMICONDUCTOR PACKAGE

(71) Applicants: Jae Choon KIM, Incheon (KR); Jin-Kwon BAE, Hwaseong-si (KR); Eunho JUNG, Seoul (KR)

(72) Inventors: Jae Choon KIM, Incheon (KR); Jin-Kwon BAE, Hwaseong-si (KR); Eunho JUNG, Seoul (KR)

(21) Appl. No.: 14/134,580

(22) Filed: Dec. 19, 2013

(30) Foreign Application Priority Data
Feb. 27, 2013 (KR) 10-2013-0021430

(51) Int. Cl. H01L 23/34

(52) U.S. Cl. CPC H01L 23/34
USPC 257/467

(57) ABSTRACT

According to example embodiments, a semiconductor package may include a first package substrate, a first semiconductor chip on the first package substrate, and a thermistor array film on the first semiconductor chip. The thermistor array film may include a variable resistive film that covers the first semiconductor chip, and an array of electrode patterns that are connected to the variable resistive film. The array of electrode patterns may be connected to at least one of the upper and lower surfaces of the variable resistive film.

### CROSS-REFERENCE TO RELATED APPLICATIONS

This U.S. non-provisional patent application claims priority under 35 U.S.C. §119 to Korean Patent Application No. 10-2013-0021430, filed on Feb. 27, 2013 in the Korean Intellectual Property Office (KIPO), the entire contents of which are hereby incorporated by reference.

### BACKGROUND

The present disclosure herein relates to a semiconductor package.

Due to a convergence trend in which computers, communication, and broadcasts are integrated, demands for a typical application specific IC (ASIC) and an application specific standard product (ASSP) are moving to a system on chip (SoC). Moreover, a trend toward light, thin, short, and small characteristics, and high functions of IT appliances is becoming a factor for developing the SoC industry.

The SoC may be a technology intensive semiconductor technology and may be a complex system having typical various functions as one chip. A SoC type semiconductor chip may emit heat in operation. Accordingly, heat may damage the semiconductor chip.

### SUMMARY

The present disclosure relates to a semiconductor package including a thermistor array film.

According to example embodiments of inventive concepts, a semiconductor package includes: a first package substrate; a first semiconductor chip on the first package substrate; and a thermistor array film on the first semiconductor chip. The thermistor array film includes a variable resistive film on the first semiconductor chip, and an array of electrode patterns that are connected to at least one of an upper surface and a lower surface of the variable resistive film.

In example embodiments, the first semiconductor chip may be a logic chip of a system on chip type.

In example embodiments, the semiconductor packages may further include a second package substrate on the thermistor array film, the second package substrate may be electrically connected to the first package substrate, and a second semiconductor chip may be on the second package substrate. The array of electrode patterns may be electrically connected to at least one of the first and second package substrates.

In example embodiments, the semiconductor package may further include an anisotropic conductive film between the thermistor array film and the second package substrate.

In example embodiments, the anisotropic conductive film may include a dielectric film and an array of internal solder balls, and the array of internal solder balls may pass through the dielectric film.

In example embodiments, the array of electrode patterns may be on the upper surface of the variable resistive film, the semiconductor packages may further include internal solder balls between the array of electrode patterns and the second package substrate, and the internal solder balls may electrically connect the array of electrode patterns to the second package substrate.

In example embodiments, the lower surface of the variable resistive film may be on the array electrode patterns, the semiconductor package may further include internal solder balls between the array of electrode patterns and the first semiconductor chip, and the internal solder balls may electrically connect the array of electrode patterns to the first semiconductor chip.

In example embodiments, the array of electrode patterns may be extended through the variable resistive film.

In example embodiments, a package cap may be on the thermistor array film; and a conductive pattern may be inside the package cap. The array of electrode patterns may be electrically connected to the conductive pattern.

In example embodiments, the semiconductor package may further include an adhesive film between the thermistor array film and the first semiconductor chip.

In example embodiments, the semiconductor package may be configured to sense when a temperature of a part of the first semiconductor chip varies based on a change in electrical resistive in a corresponding portion of the variable resistive film adjacent that is adjacent to the part of the first semiconductor chip.

In example embodiments, the variable resistive film may include at least one of a semiconductor, a ceramic, a polymer, and a metal oxide.

According to example embodiments of inventive concepts, a semiconductor package includes: a first package substrate; a first semiconductor chip on the first package substrate; and a thermistor array film including a variable resistive film and a plurality of electrode patterns on the first semiconductor chip. The plurality of electrode patterns include an array of electrode patterns connected to the variable resistive film.

In example embodiments, the variable resistive film may include at least one of a semiconductor, a ceramic, a polymer, and a metal oxide.

In example embodiments, the semiconductor chip may include a plurality of intellectual property blocks, and the thermistor array film may be on the plurality of intellectual property blocks.

In example embodiments, the array of electrode patterns may be one of: on an upper surface of the variable resistive film, between a lower surface of the variable resistive film and an upper surface of the first semiconductor chip, and extending through the variable resistive film.

In example embodiments, the semiconductor package may further include a second package substrate on the thermistor array film, and a second semiconductor chip on the second package substrate. The first semiconductor chip may be a logic chip of a system on chip type. The second semiconductor chip may be a memory chip.

In example embodiments, the array of electrode patterns may be a first array of electrode patterns, the plurality of electrode patterns may further include a second array of electrode patterns connected to the variable resistive film, and the variable resistive film may be between the first array of electrode patterns and the second array of electrode patterns.

### BRIEF DESCRIPTION OF THE DRAWINGS

The accompanying drawings of non-limiting embodiments are included to provide a further understanding of example embodiments of inventive concepts. In the drawings:

FIG. 1 is a plan view of a semiconductor package according to example embodiments of inventive concepts;

FIG. 2A is a sectional view of a process of fabricating a semiconductor package having a section taken along line II-II′ of FIG. 1;

FIG. 2B is a sectional view taken along line II-II′ of FIG. 1;

FIGS. 3 to 7 are sectional views of semiconductor packages according to example embodiments of inventive concepts;

FIG. 8 is a perspective view of an electronic device having a semiconductor package according to example embodiments of inventive concepts;

FIG. 9 is a system block diagram of an electronic device applying a semiconductor package according to example embodiments of inventive concepts; and

FIG. 10 is a block diagram of an electronic device including a semiconductor package according to example embodiments of inventive concepts.

### DETAILED DESCRIPTION

Example embodiments will now be described more fully with reference to the accompanying drawings, in which some example embodiments are shown. Example embodiments of inventive concepts may, however, be embodied in different forms and should not be construed as limited to the embodiments set forth herein. Rather, these embodiments are provided so that this disclosure will be thorough and complete, and will fully convey the scope of inventive concepts to those of ordinary skill in the art. In the drawings, the thicknesses of layers and regions are exaggerated for clarity. Like reference numerals in the drawings denote like elements, and thus their description may be omitted. Like reference numerals refer to like elements throughout the specification.

In the following description, it will be understood that when an element or layer is referred to as being “on” another element or layer, it can be “directly on” said another element or layer, or an intervening element or layer may also be present. On the contrary, when it is described that the element is “directly on” another element, there is no interleaving element or layer. The term “and/or” includes each of the mentioned items and combinations thereof. Other words used to describe the relationship between elements or layers should be interpreted in a like fashion (e.g., “between” versus “directly between,” “adjacent” versus “directly adjacent,” “coupled” versus “directly coupled”).

The terms below, beneath, lower, above, and upper that are used to describe a location in a space may be used to easily describe correlations between one element or component and another element or component as shown in the drawings. The space related terms should be understood to include the different directions of an element when a usage or operation is performed in addition to the direction shown in the drawings. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Also, though terms like a first and a second are used to describe various elements, components and/or sections, the elements, components and/or sections are not limited to these terms. These terms are used only to differentiate one member, component or section from another one. Therefore, a first element, a first component, or a first section as will be mentioned below can be referred to as a second element, a second component, or a second section without departing from the teachings of example embodiments.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof. Expressions such as “at least one of,” when preceding a list of elements, modify the entire list of elements and do not modify the individual elements of the list.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of example embodiments. Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

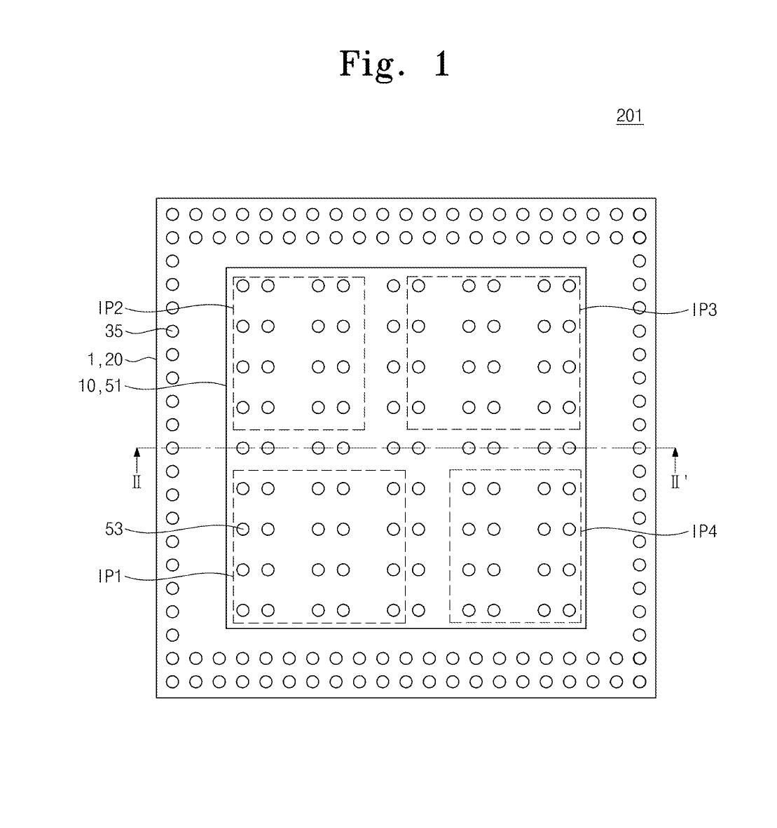

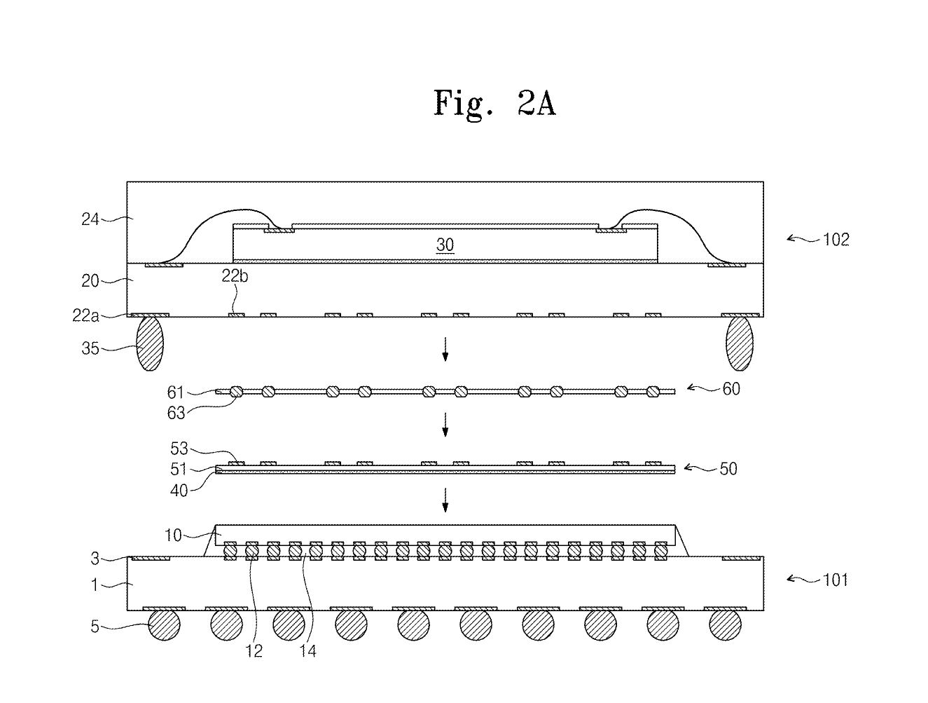

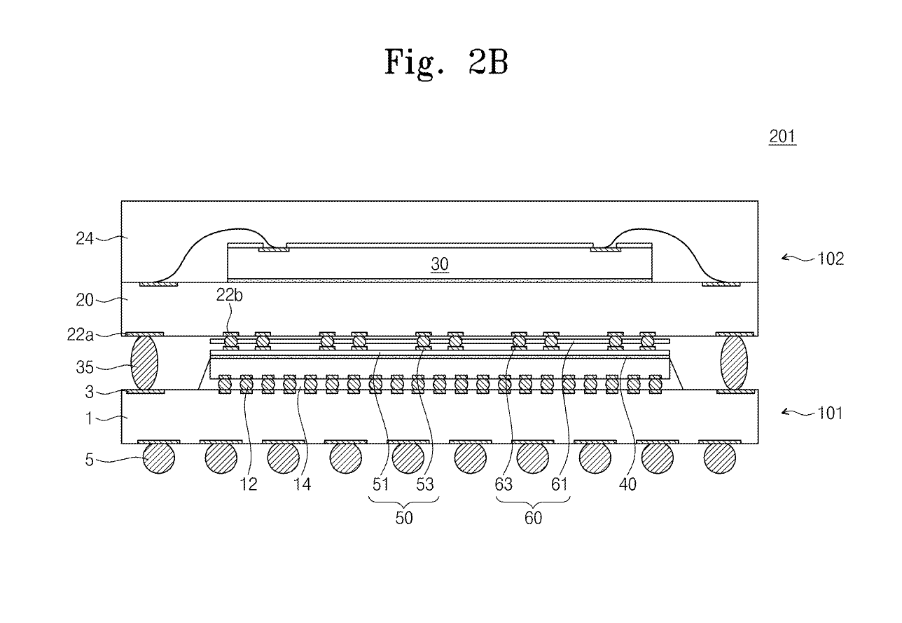

FIG. 1 is a plan view of a semiconductor package according to example embodiments of inventive concepts. FIG. 2A is a sectional view of a process of fabricating a semiconductor package having a section taken along line II-II′ of FIG. 1. FIG. 2B is a sectional view taken along line II-II′ of FIG. 1.

Referring to FIGS. 1, 2A, and 2B, in order to manufacture a semiconductor package 201 according to example embodiments of inventive concepts, a first sub semiconductor package 101 is formed. For the first sub semiconductor package 101, a first semiconductor chip 10 may be mounted by first internal solder balls 12 on a first package substrate 1 through a flip chip bonding process. An underfill resin film 14 may be filled between the first package substrate 1 and the first semiconductor chip 10. External solder balls 5 are attached to the lower surface of the first package substrate 1. Upper ball lands 3 are arranged on the edges of the upper surface of the first package substrate 1. The first semiconductor chip 10 may be a logic chip of a system on chip type. The first semiconductor chip 10 may be a logic chip that has a plurality of intellectual property (IP) blocks IP1 to IP4. The intellectual property blocks IP1 to IP4 may correspond to various devices such as a central processing unit (CPU), a graphic processing unit (GPU), and a universal serial bus (USB). However, example embodiments of inventive concepts are not limited thereto.

A thermistor array film 50 is adhered onto the first semiconductor chip 10 through an adhesive film 40. The thermistor array film 50 may include a variable resistive film 51 having an electrical resistance that varies according to a temperature, and electrode patterns 53 that are arranged in an array type. The variable resistive film 51 may be formed of at least one of a semiconductor, a ceramic, a polymer, and a metal oxide. The electrode patterns 53 may be arranged on the upper surface of the variable resistive film 51.

An anisotropic conductive film 60 is attached onto the thermistor array film 50. The anisotropic conductive film 60 may include a dielectric film 61 and second internal solder balls 63 that are arranged in an array through the dielectric film. The second internal solder balls 63 may vertically face the electrode patterns 53.

A second sub semiconductor package 102 is mounted on the first sub semiconductor package 101. For the second sub semiconductor package 102, a second semiconductor chip 30 may be mounted on a second package substrate 20 by using a wire bonding process. The second semiconductor chip 30 may be a memory chip, for example. The second semiconductor chip 30 and the second package substrate 20 may be covered with a mold film 24. First lower ball lands 22a may be arranged on the edges of the lower surface of the second package substrate 20 and second lower ball lands 22b may be arranged on the central part thereof. The second internal solder balls 63 may be in contact with both the electrode patterns 53 and the second lower ball lands 22b and electrically connect them. The upper ball lands 3 and the first lower ball lands 22a may be connected by connection solder balls 35. As such, a semiconductor package apparatus 201 may have a package on package structure.

If the temperature of any one of the IP blocks IP1 to IP4 of the first semiconductor chip 10 or any part thereof increases while the semiconductor package 201 operates, the temperature of the variable resistive film 51 adjacent to the part increases and thus electrical resistance changes. Then, it is possible to measure the electrical resistance between electrical patterns 53 adjacent to the part and thus identify which part has increased in temperature. In addition, in order to lower the temperature of the part, it is possible to change the operation of the first semiconductor chip 10, such as to decrease power consumption by adjusting the frequency of a CPU, for example. Since temperature sensors are arranged in an array type and thus it is possible to accurately measure a temperature by each part, it is possible to reduce (and/or minimize) the frequency loss of the CPU and enhance an operating speed. Moreover, since the temperature sensors are arranged outside the first semiconductor chip 10, it is possible to decrease the size of the first semiconductor chip 10 as compared to when the temperature sensors are arranged inside the first semiconductor chip 10.

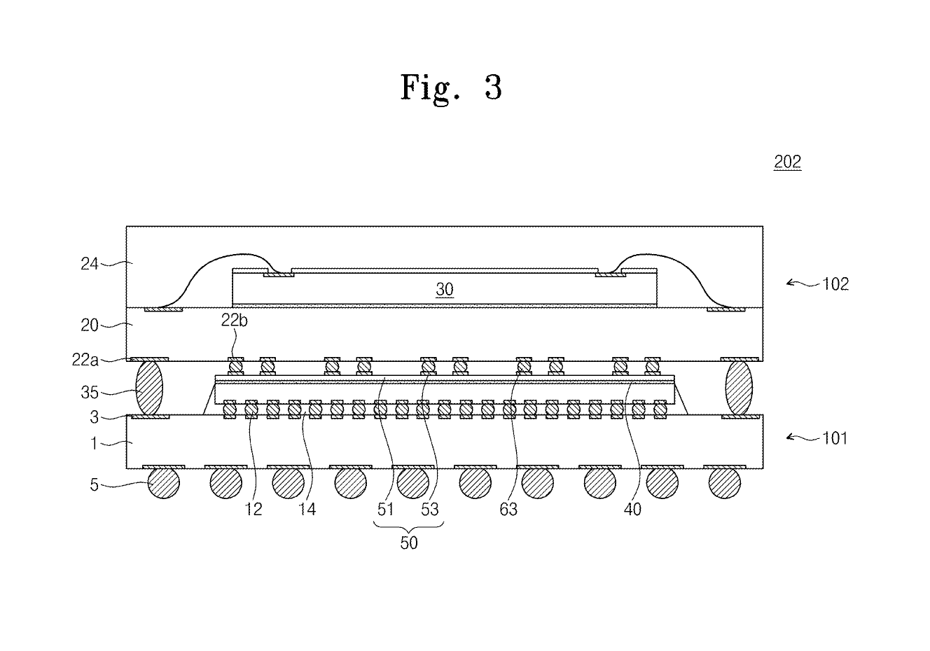

FIGS. 3 to 7 are sectional views of semiconductor packages according to example embodiments of inventive concepts.

Referring to FIG. 3, in a semiconductor package apparatus 202 according to example embodiments of inventive concepts, the electrode patterns 53 of the thermistor array film 50 and the second lower ball lands 22b of the second package substrate 20 are connected by the second internal solder balls 63. The anisotropic conductive film 60 of FIG. 2B is not disposed between the thermistor array film 50 and the second package substrate 20. Other configurations may be the same as or similar to the description made with reference to FIG. 2B.

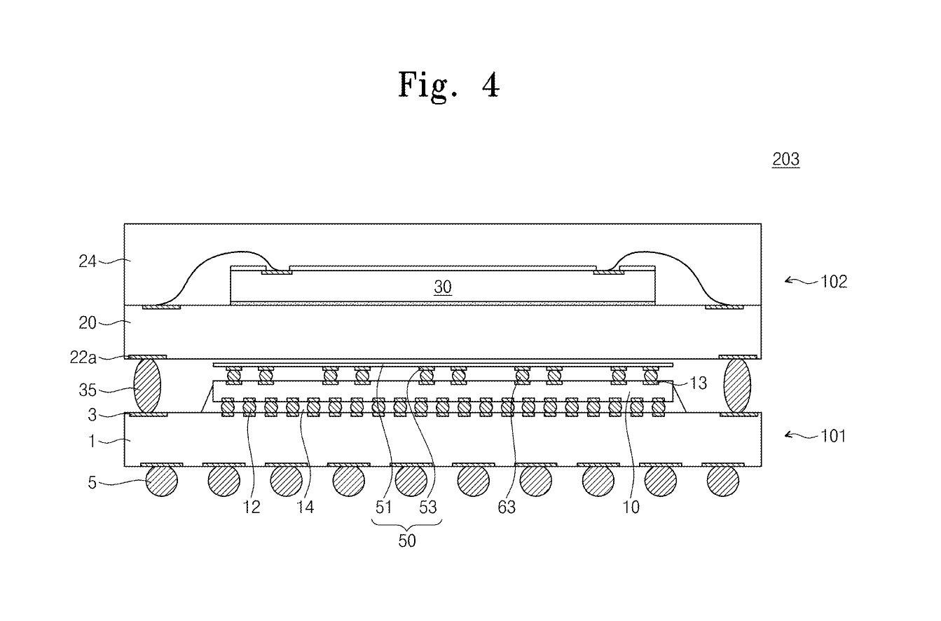

Referring to FIG. 4, in a semiconductor package apparatus 203 according to example embodiments of inventive concepts, the electrode patterns 53 of the thermistor array film 50 are arranged on the lower surface of the variable resistive film 51. Conductive pads 13 are arranged in an array type on the upper surface of the first semiconductor chip 10. The electrode patterns 53 are connected by the conductive pads 13 and the second internal solder balls 63. As shown in FIG. 4, there may be no second lower ball lands 22b on the lower surface of the second package substrate 20 of FIG. 2B. The heat generated from the first semiconductor chip 10 may be transferred to the variable resistive film 51 through the conductive pad 13, the second internal solder ball 63, and the electrode pattern 53, and change the electrical resistance of the variable resistive film 51. Other configurations may be the same as or similar to the description made with reference to FIG. 3.

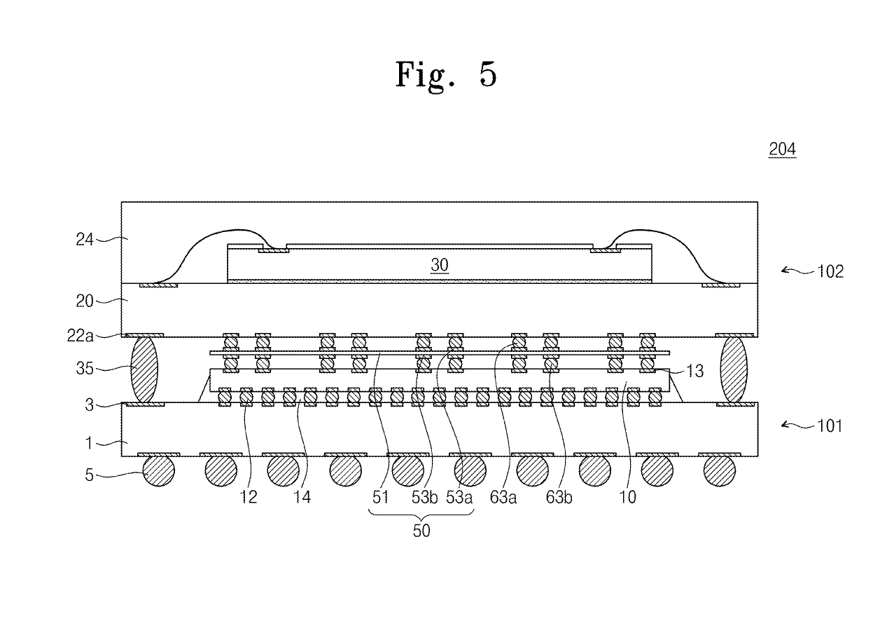

Referring to FIG. 5, in a semiconductor package apparatus 204 according to example embodiments of inventive concepts, first and second electrode patterns 53a and 53b in the thermistor array film 50 may be respectively arranged on the upper surface and lower surface of the variable resistive film 51 in an array type. The first and second electrode patterns 53a and 53b may vertically face each other. The second lower ball lands 22b may be arranged in an array type on the lower surface of the second package substrate 20 and the conductive pads 13 may be arranged in an array type on the upper surface of the first semiconductor chip 10. The first electrode patterns 53a and the second lower ball lands 22b are 1:1 connected by the second internal solder balls 63a, and the second electrode patterns 53a and the conductive pads 13 are 1:1 connected by the third internal solder balls 63b. It is possible to measure the electrical resistance between the first and second electrode patterns 53a and 53b that vertically face each other. Other configurations may be the same as or similar to the description made with reference to FIG. 4.

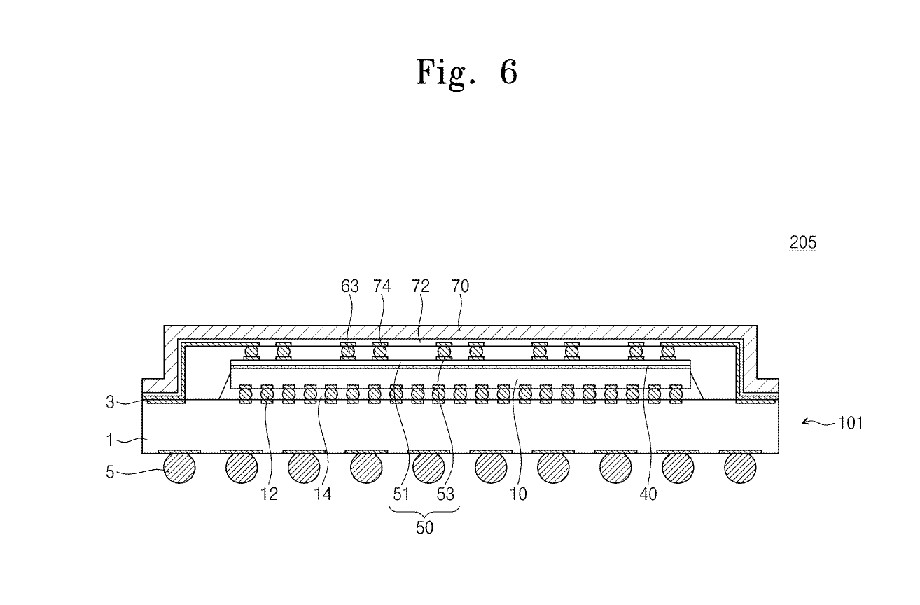

Referring to FIG. 6, a semiconductor package apparatus 205 according to example embodiments of inventive concepts may configured without a package on package structure. The semiconductor package apparatus 205 may be covered with a package cap 70 after the thermistor array film 50 is attached onto the first sub semiconductor package 101. The package cap 70 may be formed of metal. A dielectric film 72 and conductive patterns 74 may be formed on the internal surface of the package cap 70. The electrode pattern 53 of the thermistor array film 50 and the conductive pattern 74 may be connected by the second internal solder ball 63. The conductive pattern 74 may be electrically connected to the upper ball land 3 that is arranged on the upper surface of the first package substrate 1. The semiconductor package apparatus 205 according may accurately measure a temperature of each part of the first semiconductor chip 10. Moreover, the package cap 70 may function as a heat spreader or heat sink that emits, to the outside, heat generated from the first semiconductor chip 10. Thus, since the package cap 70 emits heat, it is possible to limit (and/or prevent) the semiconductor chip 10 from malfunctioning due to a high temperature and thus enhance reliability. The package cap 70 may function as an electromagnetic wave shield. Other configurations may be the same as or similar to the description made with reference to FIG. 2B

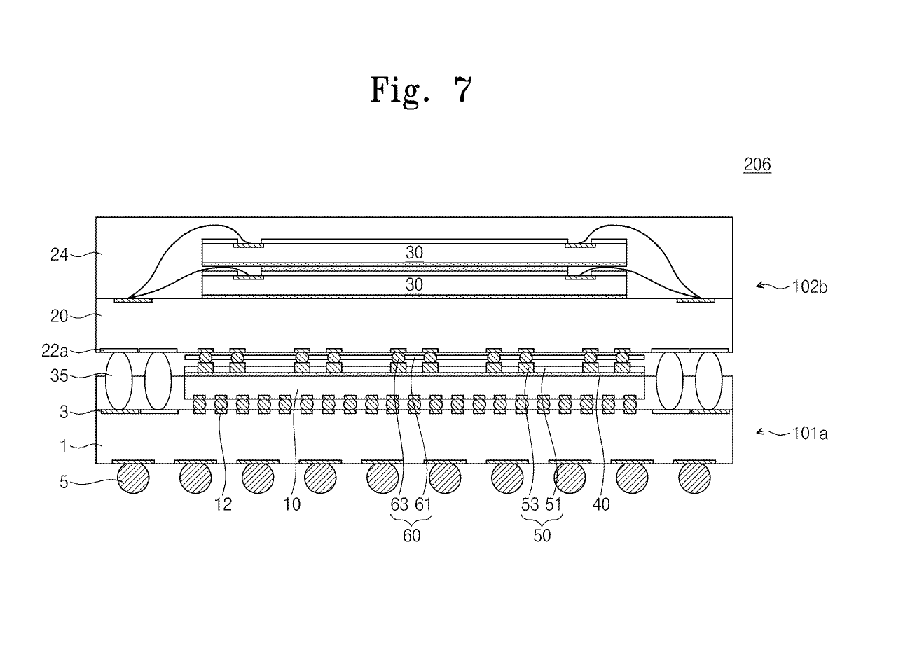

Referring to FIG. 7, in a semiconductor package apparatus 206 according to example embodiments of inventive concepts, a second sub semiconductor package 102a may be mounted on a first sub semiconductor package 101a. For the first sub semiconductor package 101a, the first semiconductor chip 10 may be mounted by the first internal solder balls 12 on the first package substrate 1 by using a flip chip bonding process. The sides of the first semiconductor chip 10 and the first package substrate 1 are covered with a first mold film 36. The first mold film may be extended and thus disposed between the first semiconductor chip 10 and the first package substrate 1. The first mold film 36 does not cover but exposes the upper surface of the first semiconductor chip 10. The first mold film 36 may have an upper surface that makes a common plane with the upper surface of the first semiconductor chip 10. The thermistor array film 50 is attached onto the first semiconductor chip 10 through the adhesive film 40. The thermistor array film 50 includes the variable resistive film 51 and the conductive patterns 53 that are arranged through the variable resistive film 51. The anisotropic conductive film 60 is arranged on the thermistor array film 50. For the second sub semiconductor package 102a, a plurality of semiconductor chips 30 may be stacked and mounted on the second package substrate 20 by using a wire bonding process. Connection solder balls that connect the first sub semiconductor package 101a to the second sub semiconductor package 102a may be arranged in a plurality of rows. It may be possible to measure the electrical resistance of the variable resistive film 51 between the electrode patterns 53. Other configurations may be the same as or similar to the description made in FIGS. 1, 2A, and 2B.

Semiconductor package technology according to example embodiments of inventive concepts may be applied to various types of semiconductor devices and a package module having them.

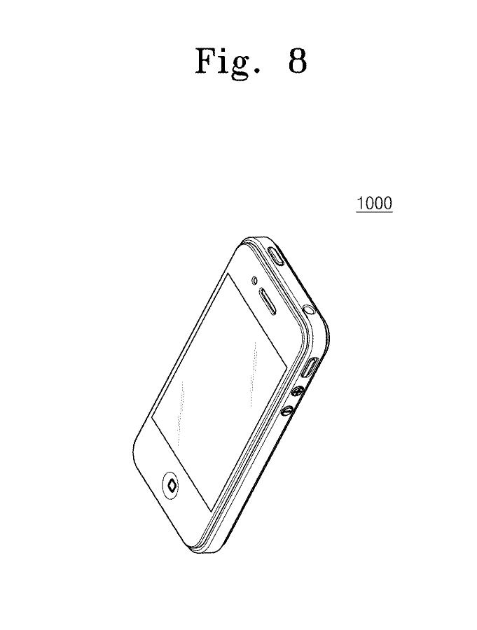

FIG. 8 is a perspective view of an electronic device having a semiconductor package according to example embodiments of inventive concepts.

Referring to FIG. 8, a semiconductor package according to example embodiments of inventive concepts may be applied to an electronic device 1000 such as a smart phone. Since a semiconductor package according to example embodiments of inventive concepts may be excellent in terms of a size decrease and performance enhancement, it may be advantageous for the light, thin, short and small characteristics of the electronic device 1000 that simultaneously implements various functions. The electronic device is not limited to the smart phone as shown in FIG. 8, it may include various electronic appliances such as a mobile electronic appliance, a laptop computer, a portable computer, a portable multimedia player (PMP), an MP3 player, a camcorder, a web tablet, a wireless phone, a navigation device, a personal digital assistant (PDA), etc.

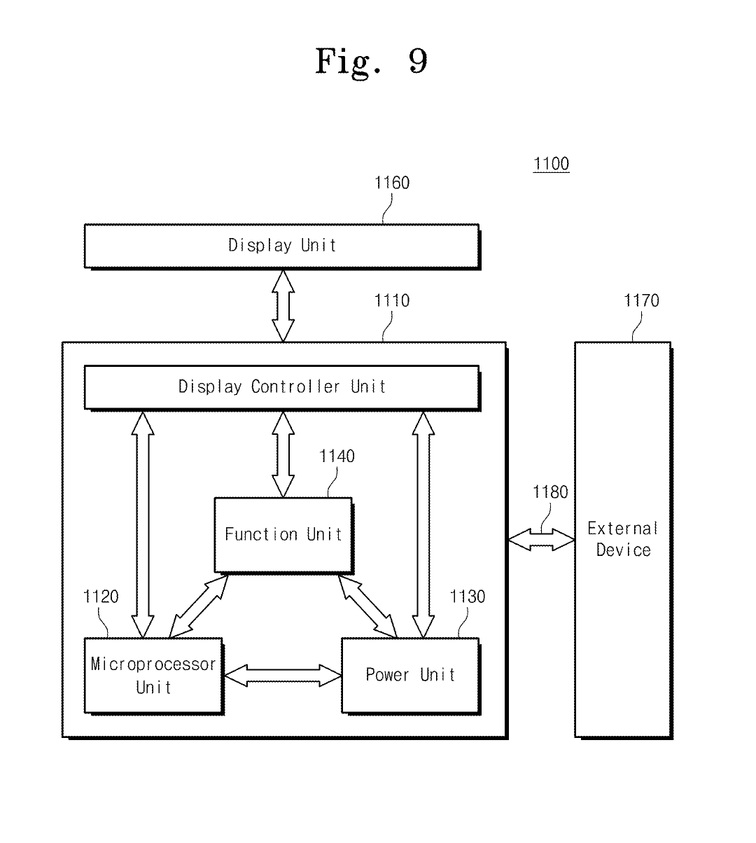

FIG. 9 is a system block diagram of an electronic device applying a semiconductor package according to example embodiments of inventive concepts.

Referring to FIG. 9, the above-described semiconductor packages 201 to 206 may be applied to an electronic device 1100. The electronic device 1100 may include a body 1110, a microprocessor unit 1120, a power unit 1130, a function unit 1140, and a display controller unit 1150. The body may include a set board that is formed as a printed circuit board, and the microprocessor unit 1120, the power unit 1130, the function unit 1140, and the display controller unit 1150 may be mounted on the body 1110.

The power unit 1130 receives a certain voltage from an external battery (not shown), divides it into desired voltage levels, and supplies the divided voltage to the microprocessor unit 1120, the function unit 1140, and the display controller unit 1150.

The microprocessor unit 1120 may receive a voltage from the power unit 1130 and control the function unit 1140 and the display unit 1160. The function unit 1140 may function as various electronic systems 1100. For example, when the electronic system 1100 is a portable phone, the function unit 1140 may include various components that may perform the functions of the portable phone, such as dialing, displaying an image on the display unit 1160 in communication with an external apparatus 1170, and outputting a voice through a loud speaker. When the electronic system 1100 has a camera, the function unit 1140 may be a camera image processor. For example, when the electronic system 1100 is connected to a memory card to increase storage capacity, the function unit 1140 may be a memory card controller. The function unit 1140 may send and receive a signal to and from the external apparatus 1170 through a wired or wireless communication unit 1180. For example, when the electronic system 1100 needs a universal serial bus (USB) to add functions, the function unit 1140 may be an interface controller. The semiconductor packages 201 to 206 according to example embodiments of inventive concepts may be used for at least one of the microprocessor unit 1120 and the function unit 1140.

The above-described semiconductor package technology may be applied to the electronic system.

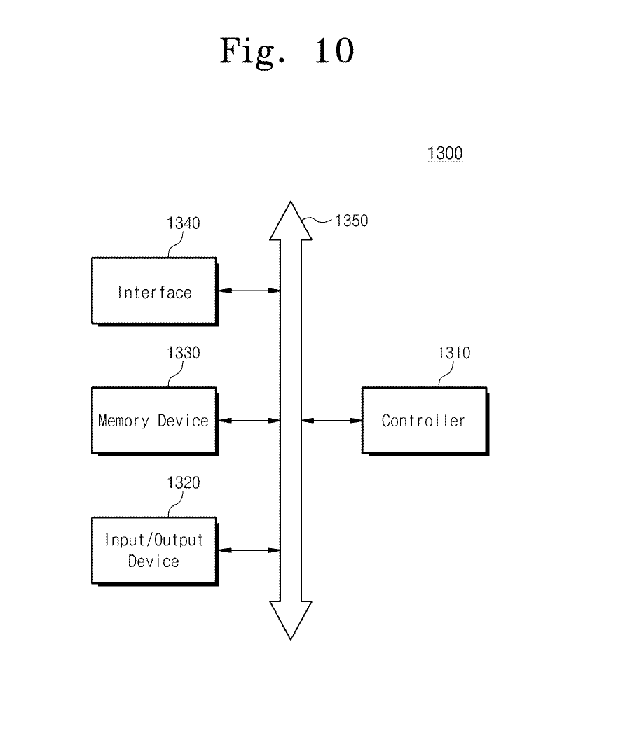

FIG. 10 is a block diagram of an electronic device including a semiconductor package according to example embodiments of inventive concepts.

Referring to FIG. 10, an electronic system 1300 may include a controller 1310, an input/ output device 1320, and a memory device 1330. The controller 1310, the input/output device 1320, and the memory device 1330 may be connected through a bus 1350. The bus 1350 may be referred to as a path through which data flows. For example, the controller 1310 may include at least one of at least one microprocessor, a digital signal processor, a microcontroller, and logic devices that may perform the same functions as these processors. The controller 1310 and the memory device 1330 may include a package on package device according to the inventive concept. The input/output device 1320 may include at least one of a keypad, a keyboard, and a display device. The memory device 1330 is a device for storing data. The memory device 1330 may store data and/or commands that are executed by the controller 1310. The memory device 1330 may include a volatile memory device and/or a non-volatile memory device. Alternatively, the memory device 1330 may be formed as a flash memory. Such a flash memory may consist of a semiconductor disk device. In this case, the electronic system 1300 may stably store massive data in the memory device 1330. The electronic system 1300 may further include an interface 1340 for transmitting or receiving data to or from a communication network. The interface 1340 may have a wired or wireless type. For example, the interface 1340 may include an antenna or a wired or wireless transceiver. In addition, although not shown, it is obvious to a person ordinary skill in the art that the electronic system 1300 may further include application chipset, a camera image processor (CIS), and an input/output device.

A semiconductor package according to example embodiments of inventive concepts may include a thermistor array film and accurately measure a temperature of each part of a semiconductor chip. Accordingly, it is possible to reduce (and/or minimize) a frequency loss of a CPU and enhance an operating speed thereof. Moreover, since a temperature sensor is arranged outside the semiconductor chip, it is possible to decrease a horizontal size of the semiconductor chip as compared to when the temperature sensor is arranged inside the semiconductor chip.

It should be understood that example embodiments described herein should be considered in a descriptive sense only and not for purposes of limitation. Descriptions of features or aspects within each device or method according to example embodiments of inventive concepts should typically be considered as available for other similar features or aspects in other devices or methods according to example embodiments of inventive concepts.

While some example embodiments of inventive concepts have been particularly shown and described, it will be understood by one of ordinary skill in the art that variations in form and detail may be made therein without departing from the spirit and scope of the claims.

What is claimed is:

1. A semiconductor package comprising:
a first package substrate;
a first semiconductor chip on the first package substrate; and
a thermistor array film on the first semiconductor chip, the thermistor array film including a variable resistive film that covers the first semiconductor chip, and an array of electrode patterns that are connected to at least one of an upper surface and an lower surface of the variable resistive film.

2. The semiconductor package of claim 1, wherein the first semiconductor chip is a logic chip of a system on chip type.

3. The semiconductor package of claim 1, further comprising:
a second package substrate on the thermistor array film, the second package substrate being electrically connected to the first package substrate; and
a second semiconductor chip on the second package substrate,
wherein the array of electrode patterns are electrically connected to at least one of the first and second package substrates.

4. The semiconductor package of claim 3, further comprising:
an anisotropic conductive film between the thermistor array film and the second package substrate.

5. The semiconductor package of claim 4, wherein
the anisotropic conductive film comprises a dielectric film and an array of internal solder balls, and
the array of internal solder balls pass through the dielectric film.

6. The semiconductor package of claim 3, wherein
the array of electrode patterns are on the upper surface of the variable resistive film,
the semiconductor package further comprises internal solder balls between the array of electrode patterns and the second package substrate, and
the internal solder balls electrically connect the array of electrode patterns to the second package substrate.

7. The semiconductor package of claim 1, wherein
the lower surface of the variable resistive film is on the array of electrode patterns,
the semiconductor package further comprises internal solder balls between the array of electrode patterns and the first semiconductor chip, and
the internal solder balls electrically connect the array of electrode patterns to the first semiconductor chip.

8. The semiconductor package of claim 1, wherein the array of electrode patterns are extended through the variable resistive film.

9. The semiconductor package of claim 1, further comprising:
a package cap on the thermistor array film; and
a conductive pattern inside the package cap, wherein
the array of electrode patterns is electrically connected to the conductive pattern.

10. The semiconductor package of claim 1, further comprising:
an adhesive film between the thermistor array film and the first semiconductor chip.

11. The semiconductor package of claim 1, wherein the semiconductor package is a configured to sense when a temperature of a part of the first semiconductor chip varies based on using a change in electrical resistance in a corresponding portion of the variable resistive film that is adjacent to the part of the first semiconductor chip.

12. The semiconductor package of claim 1, wherein the variable resistive film includes at least one of a semiconductor, a ceramic, a polymer, and a metal oxide.

13. A semiconductor package comprising:
a first package substrate;
a first semiconductor chip on the first package substrate; and
a thermistor array film including a variable resistive film and a plurality of electrode patterns on the first semiconductor chip, the plurality of electrode patterns including an array of electrode patterns connected to the variable resistive film.

14. The semiconductor package of claim 13, wherein the variable resistive film includes at least one of a semiconductor, a ceramic, a polymer, and a metal oxide.

15. The semiconductor package of claim 13, wherein
the semiconductor chip includes a plurality of intellectual property blocks, and
the thermistor array film is on the plurality of intellectual property blocks.

16. The semiconductor package of claim 13, wherein the array of electrode patterns is one of:
on an upper surface of the variable resistive film,
between a lower surface of the variable resistive film and an upper surface of the first semiconductor chip, and
extending through the variable resistive film.

17. The semiconductor package of claim 13, further comprising:
a second package substrate on the thermistor array film; and
a second semiconductor chip on the second package substrate, wherein
the first semiconductor chip is a logic chip of a system on chip type, and
the second semiconductor chip is a memory chip.

18. The semiconductor package of claim 13, wherein
the array of electrode patterns is a first array of electrode patterns,
the plurality of electrode patterns further includes a second array of electrode patterns connected to the variable resistive film, and
the variable resistive film is between the first array of electrode patterns and the second array of electrode patterns.
